(19) United States
(12) Patent Application Publication
(10) Pub. No.: US 2025/0221269 A1
(43) Pub. Date: Jul. 3, 2025

(54) PROTECTIVE FILM FOR FOLDABLE DISPLAY

(71) Applicant: INNOX Advanced Materials Co., Ltd., Asan-si (KR)

(72) Inventors: Ki-Cheol YU, Asan-si (KR); Tae-Hyun Yoo, Asan-si (KR); Kyung-sil Kim, Asan-si (KR); Jin-Hwa You, Asan-si (KR)

(21) Appl. No.: 19/003,768

(22) Filed: Dec. 27, 2024

(30) Foreign Application Priority Data
Dec. 29, 2023 (KR) 10-2023-0197865
Dec. 9, 2024 (KR) 10-2024-0181616

(51) Int. Cl. H10K 59/80; H10K 77/10; H10K 102/00

(52) U.S. Cl. CPC H10K 59/873; H10K 77/111; H10K 2102/311

(57) ABSTRACT

A protective film for a foldable display, which is attached to an outer surface of a reinforcement layer and has characteristics that include preventing intrusion of foreign substance, preventing creaking sounds, and providing exterior coverage. The protective film includes an adhesive layer and a TPU layer arranged on one surface of the adhesive layer. According to ASTM D1894, the TPU layer has a static friction coefficient of 0.1 to 4 and a kinetic friction coefficient of 0.1 to 3, with respect to SUS.

### CROSS REFERENCE TO RELATED APPLICATION

This application claims priority from Korean Patent Application No. 10-2023-0197865 filed on Dec. 29, 2023, and Korean Patent Application No. 10-2024-0181616, filed on Dec. 9, 2024, each of which is incorporated herein by reference for all purposes as if fully set forth herein.

### BACKGROUND

### Field

Embodiments of the invention relate generally to a protective film for a foldable display, which is attached to an outer surface of a reinforcement layer and has characteristics that include preventing intrusion of foreign substances, preventing creaking sounds, and providing exterior coverage.

### Discussion of the Background

Foldable displays are made using flexible OLED displays, allowing a screen to be folded.

Foldable displays have the advantage of improved portability through a folding process and being able to be used as a wide screen when unfolded. A screen of a foldable display may be folded and unfolded by using a hinge, and a reinforcement member is arranged on a rear surface of the display to ensure that when the screen is folded, a folding portion is perfectly folded, and when the screen is unfolded, a flat wide screen is shown without any trace of a folded border.

It is important for such a reinforcement member to be durable enough to be folded and unfolded tens of thousands of times, and to have mechanical durability to support and protect a display portion from mechanical stress that may occur during folding.

A folding region of the reinforcement has a lattice structure considering folding characteristics, but the folding region has the problem of easily allowing foreign substances to enter, and in some cases, metal layers are attached to an outer surface of the reinforcement member with respect to the folding region, and in such cases, when the foldable display is opened, the metal layers come into contact with each other, causing a creaking sound.

Therefore, there is a need for a protective film for a foldable display, which has excellent characteristics that include preventing intrusion of foreign substances and preventing creaking sounds, and which is capable of exhibiting improvement in exterior visibility.

The above information disclosed in this Background section is only for understanding of the background of the inventive concepts, and, therefore, it may contain information that does not constitute prior art.

### SUMMARY

Embodiments of the invention provide a protective film for a foldable display, which is attached to an outer surface of a folding plate and has characteristics that include preventing intrusion of foreign substance, preventing creaking sounds, and providing exterior coverage.

According to one or more embodiments of the invention, a protective film includes: an adhesive layer; and a thermoplastic polyurethane (“TPU”) layer arranged on one surface of the adhesive layer, and according to American Society for Testing and Materials (“ASTM”) D1894, the TPU layer has a static friction coefficient of 0.1 to 4 and a kinetic friction coefficient of 0.1 to 3, with respect to steel use stainless (“SUS”).

The TPU layer may have an optical density (“OD”) of at least 1.0.

According to ASTM D882, the TPU layer may have a tensile strength of 6 MPa to 200 MPa.

According to ASTM D882, the TPU layer may have an elongation of 300% to 1,000%.

The TPU layer may satisfy a relaxation rate of Expression 1, where Expression 1 is expressed as 50%≤{(L_{A}−L_{B})/L_{A}}×100≤100%, L_{A} is a strain when the TPU layer is fixed at a constant strain of 5% in a longitudinal direction for 10 minutes, and L_{B} is a strain measured in the longitudinal direction after 10 minutes of recovery, after the TPU layer is fixed at a constant strain of 5% in the longitudinal direction for 10 minutes

The TPU layer may have a storage modulus of 100 MPa to 2,000 MPa at −20° C. and may have a storage modulus of 1 MPa to 500 MPa at 25° C.

The TPU layer may include a polyurethane resin, which is a reaction product of polyol and isocyanate, and the polyol may have a weight-average molecular weight of 1,000 g/mol to 300,000 g/mol.

The TPU layer may include 1 wt % to 15 wt % of a pigment, based on a total of 100 wt % of the polyurethane resin and the pigment.

The TPU layer may have a slip angle of 50° or less.

The TPU layer may have a thickness of 3 μm to 50 μm.

A display member according to embodiments of the invention may include a reinforcement member including a folding region, and the protective film as mentioned above, which is arranged on one surface of the reinforcement member.

Additional features of the inventive concepts will be set forth in the description which follows, and in part will be apparent from the description, or may be learned by practice of the inventive concepts.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a cross-sectional view of a display member according to an embodiment of the invention.

FIG. 2 is a schematic view showing a method of measuring a slip angle, according to an embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, when a component is said to be arranged on a “top portion (or bottom portion)” of another component or arranged “above (or under)” the other component, it may mean that the component may be in contact with a top surface (or bottom surface) of the other component, or between the component and the other component arranged above (or under) the component, another component may be interposed.

In addition, when a component is said to be “connected”, “combined”, or “accessible” to another component, the components may be directly connected or accessible to each other, but it is to be understood that another component may be “interposed” between the components or the components may be “connected”, “combined”, or “accessible” to each other through another component.

Hereinafter, a protective film for a foldable display, according to some embodiments of the inventive concepts, is described.

In a protective film for a foldable display, an adhesive layer requires excellent adhesive strength and low modulus, and a TPU layer attached to the adhesive layer requires excellent relaxation rate, elongation, tensile strength, storage modulus, and optical characteristics.

In the inventive concepts, intrusion of foreign substances and creaking sounds may be prevented by controlling the friction coefficient, relaxation rate, elongation, tensile strength, storage modulus, and optical characteristics of the TPU layer, and exterior coverage characteristics may be ensured by including a pigment.

The adhesive layer of the protective film includes a layer in the form of a sheet or film formed from an adhesive composition, and the TPU layer includes a layer in the form of a sheet or a film formed from a polyurethane resin composition.

A protective film according to the inventive concepts includes an adhesive layer, and a TPU layer arranged on one surface of the adhesive layer, and according to ASTM D1894, the TPU layer has a static friction coefficient of 0.1 to 4 and a kinetic friction coefficient of 0.1 to 3, with respect to SUS.

Static friction coefficient may occur when static friction force is applied, and kinetic friction coefficient may occur when kinetic friction force is applied.

Generally, when surface roughness increases, glossiness decreases, leading to an increase in friction coefficient, and this corresponds to a polyethylene terephthalate (“PET”) layer which is transferred to the TPU layer to form roughness.

The TPU layer of the inventive concepts is designed to have a low glass transition temperature in order to have high elongation and low modulus, resulting in surface stickiness, and to reduce such surface stickiness, the TPU layer has roughness formed on a surface thereof. Such roughness has the effect of reducing a friction coefficient by reducing the surface area in contact.

In this regard, the TPU layer may have a static friction coefficient of 0.1 to 4, preferably, 0.4 to 3.3. The TPU layer may have a kinetic friction coefficient of 0.1 to 3, preferably, 0.3 to 2.2.

Because the TPU layer satisfies a static friction coefficient of 0.1 to 4 and a kinetic friction coefficient of 0.1 to 3, there is an effect of reducing creaking sounds in a folding region.

The friction coefficient may be measured according to ASTM D1894 under the following conditions: test speed: 150 mm/min, average section: 30 mm to 120 mm, vertical load: 1.98 N, material subjected to friction: SUS 304/specimen: TPU layer, a release film (“MATT PET”), friction coefficient: an average value of five test results.

To form surface roughness on the TPU layer, roughness is formed on the MATT PET, and then the MATT PET having the roughness formed thereon may be transferred to the TPU layer. Accordingly, the MATT PET may satisfy a roughness Ra of 0.1 to 3 and a roughness Rz of 0.4 to 12.

As surface roughness is formed on the TPU layer, the TPU layer has a reduced surface area in contact, resulting in a low static friction coefficient and a low kinetic friction coefficient.

The TPU layer may have an optical density (OD) of at least 1.0, preferably, 3.0 to 5.0. The optical density is also referred to as optical concentration, and refers to the amount of light that, after the light of a certain intensity passes through a solution layer, reaches a certain intensity.

As the optical density (OD) of the TPU layer increases, the transmittance rate decreases, and light-blocking characteristics may be ensured, and as the optical density (OD) of the TPU layer increases, exterior visibility of the protective film may be improved.

In a case where the TPU layer has an optical density (OD) of 1.0 or less, when foreign substances intrude into an exposed portion of a processed part, outdoor visibility of a display may be high.

The optical density OD may be measured as follows by using a Haze Meter, such as an NDH7000. First, after an evaluation glass is fixed to a jig, an equipment door is closed, and a Std-Cal button is pressed. MATT PET is removed, a TPU surface is placed to face upward and fixed to the jig, the equipment door is closed, and then a measurement button is pressed to thereby check a transmittance value and calculate an O.D. value.

O.D=−log₁₀(transmittance), transmittance=transmittance rate/100

It is desirable for a protective film attached to a foldable display to ensure a tensile strength to satisfy continuous folding characteristics. Tensile strength refers to a maximum stress until a test specimen breaks in a tensile test, and the higher the tensile strength, the higher a repulsive force, and the lower the tensile strength, the less likely it is to satisfy folding durability.

In this regard, according to ASTM D882, the TPU layer may have a tensile

strength of 6 MPa to 200 MPa, or even 6 MPa to 180 MPa.

As the TPU layer satisfies a tensile strength of 6 MPa to 200 MPa, there is an advantageous effect in ensuring characteristics that include preventing intrusion of foreign substances into the folding region and preventing creaking sounds.

The tensile strength may be measured according to Universal Testing Machine ASTM D882 under the following conditions: evaluation speed: 100 mm/min, test length: width of 25 mm*length of 100 mm, evaluation section: until breakage.

The protective film attached to a foldable display requires an elongation of at least a certain level because the TPU layer is stretched according to a folding curvature, and when the elongation, which is the rate of stretching in a tensile test, is too low, the TPU layer may break during folding.

In this regard, according to ASTM D882, the TPU layer may have an elongation of 300% to 1,000%, preferably, 300% to 900%.

As the TPU layer satisfies an elongation of 300% to 1,000%, there is an advantageous effect in ensuring both foreign substance intrusion prevention characteristics and bending characteristics required for a foldable display, along with soft characteristics of the TPU layer.

The elongation may be measured according to Universal Testing Machine ASTM D882 under the following conditions: evaluation speed: 100 mm/min, test length: width of 25 mm*length of 100 mm, evaluation section: until breakage.

The TPU layer may satisfy a relaxation rate of the following Expression 1.

$$50 \% \leq \{ ( {L}_{A} - {L}_{B} ) / {L}_{A} \} \times 100 \leq 100 \% . \qquad Expression 1$$

L_{A}: a strain when the TPU layer is fixed at a constant strain of 5% in a longitudinal direction for 10 minutes.

L_{B}: a strain measured in the longitudinal direction after 10 minutes of recovery, after the TPU layer is fixed at a constant strain of 5% in the longitudinal direction for 10 minutes.

In Expression 1, L_{B} is a strain measured 10 minutes after a 5% elongation and thus may represent a value of 5% to 0%. For example, in the case of L_{B}=5%, the relaxation rate is 0, in the case of L_{B}=2.5%, the relaxation rate is 50%, and in the case of L_{B}=0%, the relaxation rate is 100%.

Likewise, as the TPU layer satisfies 50%≤{(L_{A}−L_{B})/L_{A}}×100≤100%, there is an advantageous effect in ensuring foreign substance intrusion prevention characteristics and bending characteristics required for a foldable display due to the excellent relaxation rate.

The relaxation rate may be measured according to DMA under the following conditions: temperature condition: 25° C., specimen size: length of 10 mm*width of 5 mm, evaluation condition: stress relaxation test, strain: fixed at 5% for 10 minutes, relaxation: minutes.

The TPU layer may have a storage modulus of 100 MPa to 2,000 MPa at −20° C. and may have a storage modulus of 1 MPa to 500 MPa at 25° C. The TPU layer may have a storage modulus of 200 MPa to 1,500 MPa at −20° C. and may have a storage modulus of 10 MPa to 480 MPa at 25° C.

As the TPU layer satisfies a storage modulus of 100 MPa to 2,000 MPa at −20° C. and a storage modulus of 1 MPa to 500 MPa at 25° C., it is possible to ensure both attachment characteristics and folding characteristics by controlling hard properties and soft properties of the TPU layer.

The storage modulus may be measured according to ASTM D4065 under the following conditions: each temperature section: −20° C., 25° C., specimen size: length of 10 mm*width of 5 mm, evaluation condition: force of 0.005N, frequency of 1 Hz, torque of 7 N to 9 N.

It is desirable for the TPU layer to have surface characteristics without wettability and tacky, and in this regard, the TPU layer may have a slip angle of 50° or less, preferably, 20° to 50°.

The slip angle may be measured when sliding occurs while the angle is increased by a certain amount, as shown in FIG. 2, by using a Ball Tack Tester under the following condition: test condition: Cu 25 mm*25 mm, using a 10 g weight.

The protective film attached to a foldable display may cover the folding region to block external foreign substances that may intrude, and may be formed of a material that is stretchable so as to be attached to a reinforcement member that is deformed by folding.

In this regard, the TPU layer may include thermoplastic polyurethane resin, which is a reaction product of polyol and isocyanate, and may be manufactured from a polyfunctional polyol having at least two functional groups and a polyfunctional isocyanate having at least two functional groups.

The polyol may include at least one of aromatic polyol, aliphatic polyol, and alicyclic polyol.

The polyurethane-based resin may be polyurethane formed of at least one of aliphatic polyol and alicyclic polyol. Polyol may include at least one of polyester diol, polycarbonate diol, polyolefin diol, polyether diol, polythioether diol, polysiloxane diol, polyacetal diol, and polyesteramide diol, but is not limited thereto.

In order to reduce the soft characteristics of the TPU layer and enhance the hard characteristics, it is desirable for the weight-average molecular weight of the polyol to be low.

In this regard, the polyol may have a weight-average molecular weight of 1,000 g/mol to 300,000 g/mol, preferably, 50,000 g/mol to 260,000 g/mol. As the polyol satisfies a weight-average molecular weight of 1,000 g/mol to 300,000 g/mol, hardening may be provided to the surface characteristics of the TPU layer, and low elongation may be achieved while increasing tensile strength, rigidity, and elastic characteristics.

The polyfunctional isocyanate may include at least one of aliphatic isocyanate, alicyclic isocyanate, and aromatic isocyanate.

The aliphatic isocyanate may include at least one of trimethylene diisocyanate, tetramethylene diisocyanate, hexamethylene diisocyanate, pentamethylene diisocyanate, 1,2-propylene diisocyanate, 2,3-butylene diisocyanate, 1,3-butylene diisocyanate, dodecamethylene diisocyanate, and 2,4,4-trimethylhexamethylene diisocyanate.

The alicyclic isocyanate may include at least one of 3-isocyanatemethyl-3,5,5-trimethylcyclohexyl isocyanate, 1,3-cyclopentane diisocyanate, 1,3-cyclohexane diisocyanate, 1,4-cyclohexane diisocyanate, methyl-2,4-cyclohexanediisocyanate, methyl-2,6-cyclohexanediisocyanate, 4,4′-methylenebis(cyclohexylisocyanate), and 1,4-bis(isocyanatemethyl)cyclohexane.

The aromatic isocyanate may include at least one of 1,3-phenylene diisocyanate, 4,4′-diphenyl diisocyanate, 1,4-phenylene diisocyanate, 4,4′-diphenylmethane diisocyanate, 2,4-toluene diisocyanate, 2,6-toluene diisocyanate, 4,4′-toluidine diisocyanate, 2,4,6-triisocyanate toluene, 1,3,5-triisocyanatebenzene, dianisidine diisocyanate, 4,4′-diphenyl ether diisocyanate, 4,4′,4″-triphenylmethane triisocyanate, ω,ω′-diisocyanate-1,3-dimethylbenzene, ω,ω′-diisocyanate-1,4-dimethylbenzene, ω,ω′-diisocyanate-1,4-diethylbenzene, 1,4-tetramethyl xylylene diisocyanate, and 1,3-tetramethyl xylylene diisocyanate.

In order to sufficiently increase a polymerization reaction with the polyol in the TPU layer, the isocyanate may have a weight-average molecular weight of 100 g/mol to 20,000 g/mol, preferably, 200 g/mol to 1,000 g/mol.

Polyol:isocyanate, included in the TPU layer, may be included in a weight ratio of 10 to 20:1, desirably, in a weight ratio of 12 to 18:1.

As polyol: isocyanate satisfies a weight ratio of 10 to 20:1, there is an advantageous effect in ensuring tensile strength, rigidity, elastic characteristics, and elongation.

In order to ensure the optical characteristics of the TPU layer, it is important to increase the optical density (OD), and to this end, it is possible to improve exterior visibility by including a pigment in the TPU layer.

The TPU layer may include 1 wt % to 15 wt % of a pigment, preferably, 6 wt % to 15 wt %, based on the total of 100 wt % of the polyurethane resin and the pigment.

As the TPU layer includes 1 wt % to 15 wt % of the pigment, there is an advantageous effect in ensuring the light-blocking characteristics of the protective film for a foldable display.

The TPU layer is a cured product of a composition, wherein the composition may further include, in addition to the aforementioned polyurethane resin, a known additional component, for example, common additives such as antistatic agents, molecular weight modifiers, antioxidants, aging inhibitors, curing agents, curing accelerators, ionic liquids, lithium salts, silane coupling agents, organic fillers, inorganic fillers, plasticizers, stabilizers, adhesive resins, modified resins (polyol resins, phenolic resins, acrylic resins, polyester resins, polyolefin resins, epoxy resins, epoxy-polybutadiene resins, etc.), colorants, reinforcements, fillers, surfactants, wetting agents, leveling agents, defoamers, plasticizers, dyes, pigments (coloring pigments, body pigments, etc.), treatment agents, UV blockers, fluorescent whitening agents, dispersants, thermal stabilizers, light stabilizers, UV absorbers, lubricants, and solvents.

The TPU layer may have a thickness of 3 μm to 50 μm, or even 10 μm to 20 μm.

The TPU layer satisfies a thickness of 3 μm to 50 μm and thus exhibits, as a base layer, excellent adhesive characteristics with respect to the adhesive layer and is simultaneously arranged on one surface of the reinforcement member, and thus, there is an advantageous effect in ensuring characteristics that include preventing intrusion of foreign substance into the folding region, preventing creaking sounds, and providing exterior coverage.

While the protective film is formed, the adhesive layer arranged on the TPU layer may be a cured product of a composition including acrylic resin, a crosslinking agent, and a curing agent, and a known adhesive layer may be used.

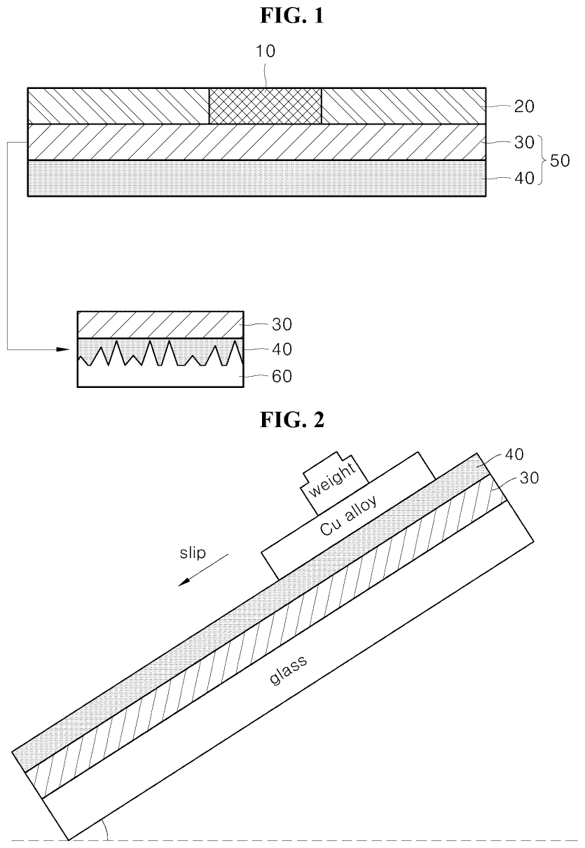

FIG. 1 is a cross-sectional view of a display member according to the inventive concepts.

As shown in FIG. 1, a display member includes a reinforcement member 20 including a folding region 10, and a protective film 50 arranged on one surface of the reinforcement member 20.

The reinforcement member 20 may be arranged on a rear surface of a display panel to support the display panel. The reinforcement member 20 may be formed of a non-metallic thin sheet material, such as fiber reinforced plastics (“FRP”) (e.g., carbon fiber reinforced plastics (“CFRP”) or glass fiber reinforced plastics (“GFRP”)), with rigid characteristics to support the display panel.

In addition, the reinforcement member may also be formed of a metal material, such as steel use stainless (“SUS”) (e.g., stainless steel (“STS”)), Cu, Al, or metal CLAD (e.g., a laminated member in which SUS and Al are alternately arranged).

The reinforcement member 20 may assist in providing rigidity reinforcement for electronic apparatuses such as displays, and may be used to shield surrounding noise and to dissipate heat emitted from a surrounding heat −emitting component.

As the protective film 50 including an adhesive layer 30 and a TPU layer 40 is attached on one surface of the reinforcement member 20, it is possible to exhibit excellent bending characteristics while having characteristics that include preventing intrusion of foreign substances, preventing creaking sounds, and providing exterior coverage.

A specific embodiment of the protective film for a foldable display is described as follows.

### 1. Manufacture of Protective Film for Foldable Display

### Specimens 1 to 8

As described in Table 1, a polyurethane resin composition was prepared by

polymerizing hexamethylene diisocyanate (“HDI”) as a trifunctional isocyanate, polyester polyol as a polyol, and a carbon black pigment.

The polyurethane resin composition was applied on a release film (“MATT PET”) and then dried at 150° C. for 4 minutes to thereby form a TPU layer having a thickness shown in Table 1, which was then aged and cured at 60° C.

Accordingly, TPU layers of specimens 1 to 8 were prepared.

### 2. Property Evaluation Methods and Results

The friction coefficient was measured according to ASTM D1894 under the following conditions: test speed: 150 mm/min, average section: 30 mm to 120 mm, vertical load: 1.98 N, material subjected to friction: SUS 304/specimen: TPU layer, MATT PET, friction coefficient: an average value of five test results.

A Haze Meter (NDH7000) was used. After an evaluation glass was fixed to a jig, an equipment door was closed, and a Std-Cal button was pressed. MATT PET was removed, a TPU surface was placed to face upward and fixed to the jig, the equipment door was closed, and then a measurement button was pressed to thereby check a transmittance value and calculate an O.D. value.

O.D=−log₁₀(transmittance), transmittance=transmittance rate/100

The tensile strength and the elongation was measured according to Universal Testing Machine ASTM D882 under the following conditions: evaluation speed: 100 mm/min, test length: width of 25 mm*length of 100 mm, evaluation section: until breakage.

The relaxation rate was measured according to DMA under the following conditions: temperature condition: 25° C., specimen size: length of 10 mm*width of 5 mm, evaluation condition: stress relaxation test, strain: fixed at 5% for 10 minutes, relaxation: 10 minutes.

The storage modulus was measured according to ASTM D4065 under the following conditions: each temperature section: −20° C., 25° C., specimen size: length of 10 mm*width of 5 mm, evaluation condition: force of 0.005N, frequency of 1 Hz, torque of 7 N to 9 N.

The slip angle was measured when sliding occurs while the angle is increased by a certain amount, as shown in FIG. 2, by using a Ball Tack Tester under the following condition: test condition: Cu 25 mm*25 mm, using a 10 g weight.

Equipment FOLDY-20T was used, and after the TPU layer was attached to a surface of a reinforcement member, folding is performed 200,000 times based on 1.5 R, and intrusion of foreign substances, tearing, and lifting inside a folding portion was checked under a microscope to determine whether foreign substances was prevented.

After the TPU layer was attached to the glass, the MATT PET was peeled off. Next, 0.1 T of SUS was put on the glass to which the TPU layer was attached, and a 500 g weight was placed thereon. After leaving it for an hour, the 500 g weight was removed, and the presence of sound was checked when 0.1 T of SUS was peeled off. When the sound was generated during peeling, it was marked as “Yes”, and when no sound was generated, it was marked as “No”.

TABLE 1

| Classification | | | | Unit | Specimen 1 | Specimen 2 | Specimen 3 |
|---|---|---|---|---|---|---|---|
| Properties | Composition | TPU | Isocyanate | g/mol | 610 | 610 | 610 |
| | | | Polyol | g/mol | 100,000 | 240,000 | 50,000 |
| | | | Pigment weight | % | 8 | 8 | 15 |
| | | MATT | Roughness Ra | μm | 0.4 | 0.4 | 0.4 |
| | | PET | Roughness Rz | μm | 3.2 | 3.2 | 3.2 |

| | | | | | |
|---|---|---|---|---|---|
| Properties | Thickness of TPU layer | μm | 16 | 16 | 16 |
| | Static friction coefficient | — | 0.74 | 3.21 | 0.4 |
| | Kinetic friction coefficient | — | 0.51 | 2.14 | 0.35 |
| | Optical density (OD) | — | 3.3 | 3.3 | 4 |
| | Tensile strength | MPa | 23 | 7 | 178 |
| | Elongation | % | 450 | 850 | 315 |
| | Relaxation rate | % | 72 | 52 | 87 |
| | Storage modulus | MPa | 150 | 16 | 450 |
| | @ 25° C. | | | | |
| | Storage modulus | MPa | 850 | 240 | 1,255 |
| | @ −20° C. | | | | |
| | Slip angle | ○ | 41 | 49 | 44 |
| | Foreign substance prevention | — | Yes | Yes | Yes |
| | Creaking sounds | — | No | No | No |

TABLE 2

| | | | | Specimen | Specimen | Specimen | Specimen | Specimen |
|---|---|---|---|---|---|---|---|---|
| Classification | | | Unit | 4 | 5 | 6 | 7 | 8 |
| Composition | TPU | Isocyanate | g/mol | 610 | 610 | 610 | 610 | 610 |
| | | Polyol | g/mol | 800 | 320,000 | 100,000 | 100,000 | 100,000 |
| | | Pigment weight | % | 8 | 8 | 0 | 30 | 8 |
| | MATT | Roughness Ra | μm | 0.4 | 0.4 | 0.4 | 0.4 | 0.09 |
| | PET | Roughness Rz | μm | 3.2 | 3.2 | 3.2 | 3.2 | 0.8 |

| | | | | | | | |
|---|---|---|---|---|---|---|---|
| Properties | Thickness of TPU | m | 16 | 16 | 16 | 16 | 16 |
| | layer | | | | | | |
| | Static friction | — | 0.63 | 4.35 | 0.81 | 0.55 | 7.1 |
| | coefficient | | | | | | |
| | Kinetic friction | — | 0.47 | 3.03 | 0.76 | 0.46 | 6.4 |
| | coefficient | | | | | | |
| | Optical density | — | 3.4 | 3.1 | 0.02 | ∞ | 3.5 |
| | (OD) | | | | | (No | |
| | | | | | | transmission) | |
| | Tensile strength | MPa | 180 | 5 | 27 | 210 | 42 |
| | Elongation | % | 85 | 1,540 | 430 | 180 | 398 |
| | Relaxation rate | % | 88 | 30 | 64 | 45 | 65 |
| | Storage modulus | MPa | 714 | 2 | 132 | 764 | 172 |
| | @ 25° C. | | | | | | |
| | Storage modulus | MPa | 2,157 | 120 | 682 | 1,845 | 867 |
| | @ −20° C. | | | | | | |
| | Slip angle | ○ | 35 | 60 | 48 | 36 | 65 |
| | Foreign substance | — | No | Yes | Yes | Yes | Yes |
| | prevention | | | | | | |
| | Creaking sounds | — | No | Yes | No | No | Yes |

From the results of Table 1, in the case of specimens 1 to 3, the polyol included in the TPU layer was within a weight-average molecular weight of 1,000 g/mol to 300,000 g/mol and the content of the pigment was within 1 wt % to 15 wt %, resulting in excellent results in terms of tensile strength, elongation, and storage modulus, as well as a small slip angle.

Accordingly, specimens 1 to 3 exhibited effects of foreign substance prevention and reduction of creaking sounds.

Specimens 1 to 3 also had high optical density, confirming their light-blocking characteristics.

In addition, in the case of specimens 1 to 3, roughness Ra of the MATT PET was within 0.1 to 3 and roughness Rz was within 0.4 to 12, and thus, surface roughness was formed on the transferred TPU layer, and accordingly, the TPU layer had a reduced surface area in contact, resulting in a low static friction coefficient and a low kinetic friction coefficient.

From the results of Table 2, in the case of specimen 4, the static friction coefficient and the kinetic friction coefficient were satisfied. However, specimen 4, which had a low weight-average molecular weight of the polyol included in the TPU layer, exhibited an extremely low elongation and an extremely high storage modulus.

Specimen 5, which had a high weight-average molecular weight of the polyol included in the TPU layer, exhibited an extremely high static friction coefficient and an extremely high kinetic friction coefficient, resulting in the slip angle exceeding 50°.

As a result, specimen 5 produced creaking sounds.

In addition, specimen 5 exhibited a low tensile strength of less than 13 MPa, an elongation exceeding 1,000%, and a relaxation rate of less than 50%.

In the case of specimen 6, which did not contain the pigment, the static friction coefficient, the kinetic friction coefficient, tensile strength, elongation, relaxation rate, and storage modulus each corresponded to the target property value of the present disclosure, the slip angle was small, and there were effects of preventing foreign substances and reducing creaking sounds.

However, because specimen 6 exhibited an optical density of less than 1, it was found that light-blocking characteristics of a protective film were almost nonexistent.

In the case of specimen 7, which had a pigment content exceeding 15%, the static friction coefficient, the kinetic friction coefficient, and the storage modulus at −20° C. each corresponded to the target property value of the present disclosure.

However, specimen 7 exhibited extremely high values for tensile strength and storage modulus at room temperature and exhibited extremely low values for elongation and relaxation rate.

In the case of specimen 8, where the roughness Ra of the MATT PET is less than 0.1, the static fiction coefficient and kinetic friction coefficient of the transferred TPU layer were greater than or equal to 5, and creaking sounds were produced.

A protective film for a foldable display, according to the present disclosure, is attached to an outer surface of a reinforcement layer and has characteristics that include preventing intrusion of foreign substance, preventing creaking sounds, and providing exterior coverage.

Along with the aforementioned effects, the specific effects of the invention are described in detail while explaining the specific details for carrying out the disclosure.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

1. A protective film comprising:
an adhesive layer; and
a thermoplastic polyurethane (“TPU”) layer arranged on one surface of the adhesive layer,
wherein, according to American Society for Testing and Materials (“ASTM”) D1894, the TPU layer has a static friction coefficient of 0.1 to 4 and a kinetic friction coefficient of 0.1 to 3, with respect to steel use stainless (“SUS’).

2. The protective film of claim 1, wherein the TPU layer has an optical density (OD) of at least 1.0.

3. The protective film of claim 1, wherein, according to ASTM D882, the TPU layer has a tensile strength of 6 MPa to 200 MPa.

4. The protective film of claim 1, wherein, according to ASTM D882, the TPU layer has an elongation of 300% to 1,000%.

5. The protective film of claim 1, wherein the TPU layer satisfies a relaxation rate of Expression 1:
50%≤{(L_{A}−L_{B})/L_{A}}×100≤100%; Expression 1:
L_{A}: a strain when the TPU layer is fixed at a constant strain of 5% in a longitudinal direction for 10 minutes; and
L_{B}: a strain measured in the longitudinal direction after 10 minutes of recovery, after the TPU layer is fixed at a constant strain of 5% in the longitudinal direction for 10 minutes.

6. The protective film of claim 1, wherein the TPU layer has a storage modulus of 100 MPa to 2,000 MPa at −20° C. and has a storage modulus of 1 MPa to 500 MPa at 25° C.

7. The protective film of claim 1, wherein:
the TPU layer comprises a polyurethane resin, which is a reaction product of polyol and isocyanate; and
the polyol has a weight-average molecular weight of 1,000 g/mol to 300,000 g/mol.

8. The protective film of claim 7, wherein the TPU layer comprises 1 wt % to 15 wt % of a pigment, based on a total of 100 wt % of the polyurethane resin and the pigment.

9. The protective film of claim 1, wherein the TPU layer has a slip angle of 50° or less.

10. The protective film of claim 1, wherein the TPU layer has a thickness of 3 μm to 50 μm.

11. A display member comprising:
a reinforcement member comprising a folding region; and
the protective film according to claim 1, which is arranged on one surface of the reinforcement member.
